(19) United States
(12) Patent Application Publication
(10) Pub. No.: US 2011/0272004 A1
(43) Pub. Date: Nov. 10, 2011

(54) Solar panels with opaque EVA film backseets

(76) Inventors: Robert F. Davis, Wilmington, DE (US); E. David Santoleri, Glen Mills, PA (US)

(21) Appl. No.: 12/800,004

(22) Filed: May 6, 2010

(51) Int. Cl. H01L 31/048

(52) U.S. Cl. 136/251

(57) ABSTRACT

Laminates of ethylene-vinyl acetate copolymer resin with opacifying pigment provide excellent performance as backing sheets for photovoltaic cells.

### BACKGROUND OF THE INVENTION

The present invention relates to solar panels characterized by improved efficiency in the generation of power.

It is well known that a white ethylene vinyl acetate (EVA) copolymer layer facing the front of a photovoltaic (PV) panel will reflect photons that miss the cells. Some of these photons will reflect back to the underside of the glass in the panel and bounce back to the cell where they will then penetrate the cell, thereby liberating electrons. However, after several years of exposure, the mid layer of polyethylene terephthalate (PET) polyester film will turn yellow and brown. This color will show through the white EVA layer if that layer is insufficiently opaque. This will reduce the level of reflectivity and result in less power being generated.

Previous attempts to solve this problem included increasing the pigment loading of a single layer EVA sheet. However, this will cause increased defects in the extruded sheet. Particle agglomeration on the surface will increase in frequency, resulting in a defective backsheet and possible breakage of the PV cells during lamination.

### SUMMARY OF THE INVENTION

The present invention provides an improved solar panel that solves the long-standing problems noted above.

Specifically, the present invention provides a solar panel comprising a front cover, a first layer of encapsulant, a plurality of photovoltaic cells, a second layer of encapsulant, and a backing sheet adjacent to the second layer of encapsulant, the backing sheet comprising: (a) a laminar structure of at least three layers comprising two outer layers and a core layer, the outer layers each consisting essentially of ethylene vinyl acetate copolymer having about from 2 to 8% vinyl acetate and each comprising up to about 6% of opacifying pigment, and wherein the core layer comprises thermoplastic olefin polymer containing about from 4 to 12% by weight of opacifying pigment;

(b) a layer of polyester film; and
(c) at least one weatherable exterior layer.

### BRIEF DESCRIPTION OF THE DRAWINGS

FIG. 1 is a schematic, cross-sectional illustration of a solar panel of the present invention.

FIG. 2 is an enlarged, schematic, cross-sectional illustration of a backing sheet which can be used in the solar panels of the present invention.

### DETAILED DESCRIPTION OF THE INVENTION

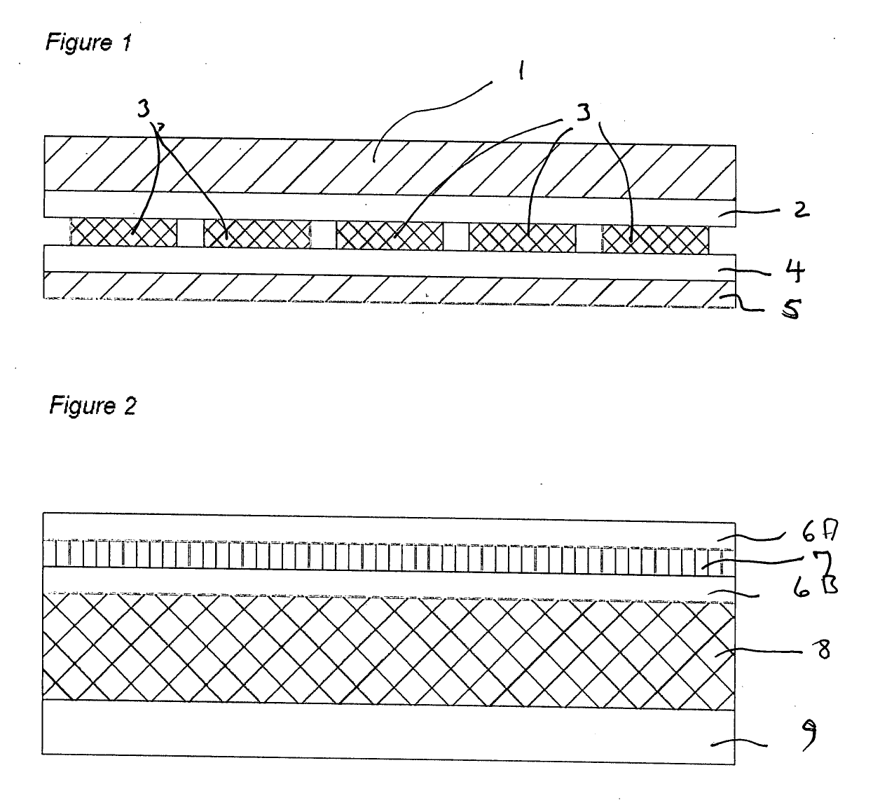

As illustrated in FIG. 1, the present invention relates to solar panels of the type comprising a front cover 1, a first layer of encapsulant 2, a plurality of photovoltaic cells 3, a second layer of encapsulant 4, and a backing sheet 5 adjacent to the encapsulant. More specifically, the present invention relates to improved backing sheets that are typically positioned adjacent to the encapsulant. Constructions of this type are generally described, for example, in Hanoka, U.S. Pat. Nos. 5,620,904, 6,353,042 and 6,187,448, each hereby incorporated by reference.

The front cover is typically glass or polymeric film such as ETFE, generally having a thickness of about 3-4 mm.

In accordance with the present invention, the backing sheet, shown in schematic cross-section in FIG. 2, comprises a laminar structure comprising two outer layers 6A and 6B and a core layer 7, the outer layers each consisting essentially of ethylene vinyl acetate copolymer having about from 2 to 8% vinyl acetate, and each comprising up to about 6% of opacifying pigment, and wherein the core layer comprises thermoplastic olefin polymer, preferably also ethylene vinyl acetate copolymer, containing about from 4 to 12% by weight of opacifying pigment. Preferably, the vinyl acetate content of each outer layer is about 4% of the copolymer.

It is preferred that each outer layer in the laminar structure of the backing sheet comprises about 3% by weight of opacifying pigment. It is also preferred that each outer layer of the laminar structure has a thickness of about from 12 to 25 microns, and especially about 17 microns. The core layer in the backing sheet is generally about from 50 to 75 microns in thickness.

The core layer in the backing sheet preferably consists essentially of at least one olefinic polymer selected from ethylene vinyl acetate and low density polyethylene. It is also preferred that the core layer comprises about from 5 to 10% by weight opacifying pigment, and especially about 8% by weight of opacifying pigment. Such structures have been found to provide particularly satisfactory performance in photovoltaic panels. The particular opacifying pigment used can vary widely, but is preferably selected from at least one of TiO₂, and BaSO₄.

It is also preferred that at least one outer layer in the laminar structure further comprises at least one ultraviolet light absorber. The particular ultraviolet light absorber can also vary widely, but is preferably selected from at least one of benzophenone, benzotriazole, and hindered amines.

The laminar structure further comprises a layer of stabilizing polymeric film 8. This layer improves the dimensional stability of the laminar structure and provides good dielectric properties. It is generally about from 50 to 250 microns in thickness. It can be selected, for example, from polyesters such as polyethylene terephthalate, polycarbonates and liquid crystal polymers, of which polyethylene terephthalate is preferred on the basis of its dielectric properties and ready availability.

Additional layers can be included to accommodate specific needs for the constructions. For example, a layer of metal foil, such as aluminum, can be used for a moisture bather. When used, such a layer would typically have a thickness of about 17-50 microns. When used, such a layer would typically be positioned between the weatherable and polyester layers.

The panels of the present invention further comprise a weatherable exterior layer, shown as element 9 in FIG. 2. This layer is generally about from 12 to 50 microns in thickness, and preferably about from 25 to 30 microns. A wide variety of opacified polymeric films can be used, including, for example, polyvinyl fluoride; polyvinylidene fluoride; polycarbonate or polycarbonate/polybutylene terephthalate films, having, for example, thicknesses of about from 37 to 100 microns; polyetherimide films having thicknesses of about from 25 to 75 microns; visually clear or opacified hydrolysis resistant polyethylene terephthalate films with ultraviolet light absorbers having thicknesses of about from 17 to 100 microns; ethylenechlorotrifluoroethlyne (ECTFE) having a thickness of about from 17 to 50 microns; coatings of perfluoroalkyl vinyl ether having thicknesses of about from 12 to 25 microns, in which the fluoropolymer segment can be either tetrafluoroethylene (TFE) or chlorotrifluoroethyene (CTFE); and ionomer based films having a thickness of about from 12 to 37 microns. Of these, polyvinyl fluoride is preferred because of its broad use in the photovoltaic industry.

The solar panels prepared according to the present invention provide improved power generation and excellent power retention characteristics over extended periods of time. The backsheets used in the present panels provide increased opacity while significantly decreasing surface particle agglomeration. The present backsheets include a coextruded film in which the outer EVA layers will be either clear or lightly pigmented, while the mid layer can be more heavily pigmented to achieve a high opacity. This results in higher reflectivity, both initially and after long term exposure. Moreover, the quality of the EVA sheet will be enhanced, as the surface will be uniform and flat. Moreover, these benefits are obtained with only a modest increase in cost over a single layer sheet.

The present invention is further illustrated by the following specific Examples and Comparative Examples.

### EXAMPLE 1 and COMPARATIVE EXAMPLE A

A photovoltaic solar panel was prepared comprising a sheet of glass, a layer of 450 micron ethylene/vinyl acetate (EVA) encapsulant, photovoltaic solar cells strung together in series, a second layer of 450 micron EVA encapsulant and a backsheet. The backsheet was prepared by laminating a 37 micron polyvinyl fluoride film to a polyethylene terephthalate film, of a thickness of 125 microns, with a diisocyanate cured urethane adhesive, followed by laminating a coextruded, pigmented thermoplastic EVA film with a VA content of 4% and a total thickness of 100 microns. The coextruded EVA film contained 4% pigment in the outer layers and 10% titanium dioxide pigment in the inner layer. The same adhesive was used to bond the EVA film to the polyethylene terephthalate film as was used to bond the polyvinyl fluoride film to the polyethylene terephthalate film.

The panel was laminated in a vacuum laminator for 15 minutes and removed hot. The laminating cycle consisted of 6 minutes of evacuation at 5 tons, 1 minute of bladder deployment to one atmosphere and finally 8 minutes of press time. The laminator maintained a constant temperature of 150 degrees Celsius.

The laminate was exposed to a temperature of 85 degrees Celsius and 85% relative humidity for 2,000 hours. In Comparative Example A, another PV solar panel was prepared according to the same procedure, except the thermoplastic EVA layer was prepared as a monolayer with a titanium dioxide content of 6% by weight. The two panels were then measured for power output. The result was the panel of Example 1, made with the coextruded EVA layer yielded about 5% more power than the panel of Comparative Example A, made with the monolayer EVA layer.

### EXAMPLE 2 and COMPARATIVE EXAMPLE B

A photovoltaic solar panel was prepared in the same way as Example 1, except that the 450 micron EVA encapsulant was replaced with a silicone encapsulant of the same thickness, and this encapsulant contained no ultra violet light absorber. To compensate, the outer layer of the coextruded, thermoplastic EVA film contained an ultraviolet absorber package, consisting of a benzophenone and a benzotriazole in the amount of 2% by weight of the outer layer. Also, the coextruded, thermoplastic EVA film contained 2% by weight of titanium dioxide and 1% by weight of barium sulfate in both outer layers and 5% by weight of titanium dioxide in the mid layer.

The solar panel was laminated as in Example 1. In Comparative Example B, another solar panel was also prepared with the same silicone encapsulant, but with a 100 micron thick monolayer EVA, thermoplastic film containing 6% by weight of titanium dioxide. The panels were exposed for 2,000 hours of damp heat at 85 degrees Celsius and 85% relative humidity. The panels were them measured for power output. The result was the panel of Example 2, made with the coextruded thermoplastic EVA film measured 7% more power than the panel of Comparative Example B, made with the monolayer thermoplastic EVA film.

We claim:

1. A solar panel comprising a front cover, a first layer of encapsulant, a plurality of photovoltaic cells, a second layer of encapsulant, and a backing sheet adjacent to the second layer of encapsulant, the backing sheet comprising:
(a) a laminar structure of at least three layers, comprising two outer layers and a core layer, the outer layers each consisting essentially of ethylene vinyl acetate copolymer having about from 2 to 8% vinyl acetate and each comprising up to about 6% of opacifying pigment, and wherein the core layer comprises thermoplastic olefin polymer containing about from 4 to 12% by weight of opacifying pigment;
(b) a layer of polyester film; and
(c) at least one weatherable exterior layer.

2. A solar panel of claim 1 wherein the vinyl acetate content of each outer layer in the laminar structure of the backing sheet is about 4% of the copolymer.

3. A solar panel of claim 1 wherein each outer layer in the laminar structure of the backing sheet comprises about 3% by weight of opacifying pigment.

4. A solar panel of claim 1 wherein each outer layer in the laminar structure of the backing sheet has a thickness of about from 12 to 25 microns.

5. A solar panel of claim 4 wherein the thickness of each outer layer in the laminar structure of the backing sheet is about 17 microns.

6. A solar panel of claim 1 wherein the thickness of the core layer in the laminar structure (a) is about from 50 to 75 microns.

7. A solar panel of claim 6 wherein the thickness of the core layer is about 65 microns.

8. A solar panel of claim 1 wherein the core layer in the laminar structure of the backing sheet consists essentially of at least one olefinic polymer selected from ethylene vinyl acetate and low density polyethylene.

9. A solar panel of claim 1 wherein the core layer in the laminar structure of the backing sheet comprises about from 6 to 10% by weight opacifying pigment.

10. A solar panel of claim 9 wherein the core layer of the laminar structure comprises about 8% by weight of opacifying pigment.

11. A solar panel of claim 9 wherein the opacifying pigment is selected from at least one of TiO₂, and BaSO₄.

12. A solar panel of claim 1 wherein at least one outer layer in the laminar structure of the backing sheet further comprises at least one ultraviolet light absorber.

13. A solar panel of claim 12 wherein the ultraviolet light absorber is selected from at least one of benzophenone, benzotriazole, and hindered amines.

14. A solar panel of claim 1 wherein the weatherable outer layer consists essentially of polyvinyl fluoride.
